(19) United States
(12) Patent Application Publication
(10) Pub. No.: US 2026/0112577 A1
(43) Pub. Date: Apr. 23, 2026

(54) SUBSTRATE PROCESSING APPARATUS

(71) Applicant: KOKUSAI ELECTRIC CORPORATION, Tokyo (JP)

(72) Inventors: Teruo YOSHINO, Toyama (JP); Yukinori ABURATANI, Toyama (JP); Takashi YAHATA, Toyama (JP)

(73) Assignee: KOKUSAI ELECTRIC CORPORATION, Tokyo (JP)

(21) Appl. No.: 19/397,365

(22) Filed: Nov. 21, 2025

Related U.S. Application Data
(63) Continuation of application No. 16/817,038, filed on Mar. 12, 2020, now abandoned.

(30) Foreign Application Priority Data
Mar. 25, 2019 (JP) 2019-056673

(51) Int. Cl. H01J 37/32; H01L 21/02

(52) U.S. Cl. CPC H01J 37/32146; H01J 37/321; H01J 37/3211; H10P 14/6309; H10P 14/69215; H01J 2237/3327

(57) ABSTRACT

There is provided a technique that includes a process chamber configured to process a substrate; a substrate-mounting part configured to support the substrate in the process chamber; a gas supply part configured to supply a gas to the process chamber; a high-frequency power supply part configured to supply high-frequency power of a predetermined frequency; a first resonance coil wound to surround the process chamber and configured by a first conductor that forms plasma at the process chamber when the high-frequency power is supplied; a second resonance coil wound to surround the process chamber and configured by a second conductor that forms plasma at the process chamber when the high-frequency power is supplied; and a controller configured to control the high-frequency power supply part so that a period of power supply to the first resonance coil does not overlap with a period of power supply to the second resonance coil.

### CROSS-REFERENCE TO RELATED APPLICATION

This non-provisional U.S. patent application is a continuation of U.S. patent application Ser. No. 16/817,038 filed on Mar. 12, 2020 and Japanese Patent Application No. 2019-056673, filed on Mar. 25, 2019, in the Japanese Patent Office, the entire contents of which are hereby incorporated by reference.

### TECHNICAL FIELD

The present disclosure relates to a substrate processing apparatus.

### BACKGROUND

In recent years, semiconductor devices such as flash memories tend to be highly integrated. Along with this, the pattern size has been significantly miniaturized. The miniaturization has an effect such as an increase in the aspect ratio of a deep groove. In that case, a gas needs to reach the back of the deep groove.

In the related art, for example, there has been proposed a technique for using a plasma-excited processing gas to treat a pattern surface formed on a substrate.

When plasma treatment is performed on a film having a groove having a high aspect ratio, it is conceivable that plasma does not reach the back of the groove. It is considered that one of the causes is that the plasma is deactivated above the groove. In this case, since the treatment on the bottom of the groove becomes insufficient, the treatment on the interior of the groove becomes uneven.

### SUMMARY

Some embodiments of the present disclosure provide a technique capable of uniformly treating the interior of a groove having a high aspect ratio.

According to one or more embodiments of the present disclosure, there is provided a technique that includes a process chamber configured to process a substrate; a substrate-mounting part configured to support the substrate in the process chamber; a gas supply part configured to supply a gas to the process chamber; a high-frequency power supply part configured to supply high-frequency power of a predetermined frequency; a first resonance coil wound to surround the process chamber and configured by a first conductor that forms plasma at the process chamber when the high-frequency power is supplied to the first resonance coil; a second resonance coil wound to surround the process chamber and configured by a second conductor that forms plasma at the process chamber when the high-frequency power is supplied to the second resonance coil; and a controller configured to control the high-frequency power supply part so that a period of power supply to the first resonance coil does not overlap with a period of power supply to the second resonance coil.

### BRIEF DESCRIPTION OF DRAWINGS

The accompanying drawings, which are incorporated in and constitute a part of the specification, illustrate embodiments of the present disclosure.

FIG. 1 is a schematic sectional view of a substrate processing apparatus.

FIG. 2 is an explanatory view for explaining the principle of plasma generation of the substrate processing apparatus.

FIG. 3 is an explanatory view for explaining the principle of plasma generation of the substrate processing apparatus.

FIG. 4 is an explanatory view for explaining the operations of a gas supply part and a high-frequency power supply part.

FIG. 5 is a view illustrating the configuration of a control part of the substrate processing apparatus.

FIG. 6 is an explanatory view of a substrate on which a groove (trench) to be processed in a substrate-processing process is formed.

FIG. 7 is a flowchart for explaining a substrate-processing process.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### (1) Configuration of Substrate Processing Apparatus

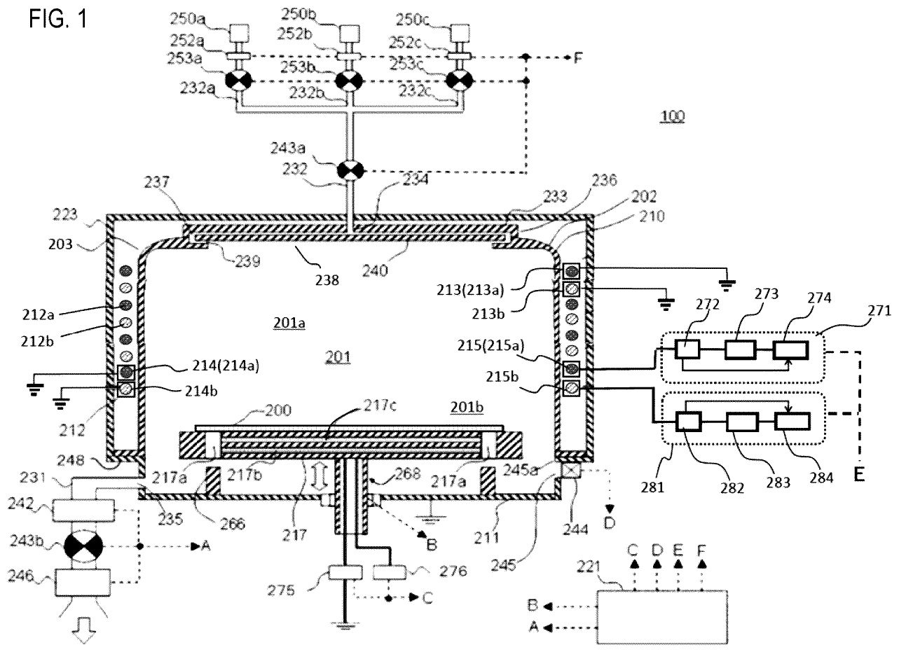

A substrate processing apparatus will be now described with reference to FIGS. 1 to 5. A substrate processing apparatus according to the present embodiments is configured to mainly perform an oxidation process to a film formed on a substrate surface.

### Process Chamber

A processing apparatus 100 includes a process furnace 202 that performs plasma treatment on a substrate 200. The process furnace 202 is provided with a processing container 203 constituting a process chamber 201. The processing container 203 includes a dome-shaped upper container 210, which is a first container, and a bowl-shaped lower container 211, which is a second container. The process chamber 201 is formed when the upper container 210 covers the lower container 211. The upper container 210 is made of, for example, a nonmetallic material such as aluminum oxide (Al₂O₃) or quartz (SiO₂), and the lower container 211 is made of, for example, aluminum (Al).

A gate valve 244 is installed at a lower side wall of the lower container 211. When the gate valve 244 is opened, the substrate 200 can be loaded into or unloaded from the process chamber 201 via a loading/unloading port 245 using a transfer mechanism (not shown). When the gate valve 244 is closed, the gate valve 244 is configured to be a gate valve that keeps an interior of the process chamber 201 airtight.

A resonance coil 212 is wound around the process chamber 201 so as to surround the process chamber 201. In the process chamber 201, a space adjacent to the resonance coil 212 is referred to as a plasma generation space 201a. A space that communicates to the plasma generation space 201a and in which the substrate 200 is processed is referred to as a substrate-processing space 201b. The plasma generation space 201a is a space in which plasma is generated, and refers to a space above the lower end of the resonance coil 212 and below the upper end of the resonance coil 212 in the process chamber 201. On the other hand, the substrate-processing space 201b is a space in which the substrate is processed using plasma, and refers to a space below the lower end of the resonance coil 212. In the present embodiments, the plasma generation space 201a and the substrate-processing space 201b are configured to have substantially the same horizontal diameter.

### Substrate-Mounting Table

A substrate-mounting table 217 serving as a substrate-mounting part on which the substrate 200 is mounted is disposed at the center of the bottom of the process chamber 201. The substrate-mounting table 217 is made of, for example, a nonmetallic material such as aluminum nitride (AlN), ceramics, quartz, or the like, and is configured to reduce metal contamination on a film or the like formed on the substrate 200. The substrate-mounting table 217 is also referred to a substrate-mounting part.

A heater 217b serving as a heating mechanism is embedded in the substrate-mounting table 217. When power is supplied to the heater 217b, the heater is able to heat the surface of the substrate 200, for example, from about 25 degrees C. to about 750 degrees C.

The substrate-mounting table 217 is electrically isolated from the lower container 211. An impedance adjustment electrode 217c is installed inside the substrate-mounting table 217 in order to further improve the uniformity of the density of plasma generated on the substrate 200 mounted on the substrate-mounting table 217, and is grounded via an impedance-variable mechanism 275 serving as an impedance adjustment part.

The impedance-variable mechanism 275 is composed of a resonance coil and a variable capacitor. By controlling the inductance and resistance of the resonance coil and the capacitance of the variable capacitor, the impedance can be changed within a range from about 0Ω to the parasitic impedance of the process chamber 201. Thus, the potential (bias voltage) of the substrate 200 can be controlled via the impedance adjustment electrode 217c and the substrate-mounting table 217.

In the present embodiments, since the uniformity of the density of the plasma generated on the substrate 200 can be improved as described below, when the uniformity of the density of the plasma falls within a desired range, bias voltage control using the impedance adjustment electrode 217c is not performed. When the bias voltage control is not performed, the electrode 217c may not be provided at the substrate-mounting table 217. However, the bias voltage control may be performed for the purpose of further improving the uniformity.

The substrate-mounting table 217 is provided with a substrate-mounting-table-elevating mechanism 268 including a drive mechanism for moving the substrate-mounting table up and down. Further, through-holes 217a are formed at the substrate-mounting table 217, and wafer push-up pins 266 are installed at the bottom surface of the lower container 211. At least three through-holes 217a and at least three wafer push-up pins 266 are provided at positions facing each other. When the substrate-mounting table 217 is lowered by the substrate-mounting-table-elevating mechanism 268, the wafer push-up pins 266 are configured to penetrate through the through-holes 217a in a state of not being in contact with the substrate-mounting table 217.

### Gas Supply Part

A gas supply head 236 is installed above the process chamber 201, that is, above the upper container 210. The gas supply head 236 includes a cap-shaped lid 233, a gas inlet 234, a buffer chamber 237, an opening 238, a shielding plate 240, and a gas outlet 239, and is configured to supply a reaction gas into the process chamber 201. The buffer chamber 237 has a function as a dispersion space for dispersing the reaction gas introduced from the gas inlet 234.

The gas inlet 234 is connected with a joining pipe 232 at which the downstream end of an oxygen-containing gas supply pipe 232a for supplying an oxygen (O₂) gas as an oxygen-containing gas, the downstream end of a hydrogen-containing gas supply pipe 232b for supplying a hydrogen (H₂) gas as a hydrogen-containing gas, and an inert gas supply pipe 232c for supplying an argon (Ar) gas as an inert gas are joined.

The oxygen-containing gas supply pipe 232a is provided with an O₂ gas supply source 250a, a mass flow controller (MFC) 252a as a flow rate control device, and a valve 253a as an opening/closing valve in this order from the upstream side. An oxygen gas supply part includes the oxygen-containing gas supply pipe 232a, the MFC 252a, and the valve 253a. The oxygen gas supply part is also referred to as a first processing gas supply part.

The hydrogen-containing gas supply pipe 232b is provided with a H₂ gas supply source 250b, an MFC 252b, and a valve 253b in this order from the upstream side. A hydrogen-containing gas supply part includes the hydrogen-containing gas supply pipe 232b, the MFC 252b, and the valve 253b. The hydrogen-containing gas supply part is also referred to as a second processing gas supply part.

The inert gas supply pipe 232c is provided with an Ar gas supply source 250c, an MFC 252c, and a valve 253c in this order from the upstream side. An inert gas supply part includes the inert gas supply pipe 232c, the MFC 252c, and the valve 253c.

A valve 243a is installed at the downstream side where the oxygen-containing gas supply pipe 232a, the hydrogen-containing gas supply pipe 232b, and the inert gas supply pipe 232c are joined, and is configured to communicate with the gas inlet 234. While adjusting the flow rates of the respective gases by the MFCs 252a, 252b, and 252c by opening and closing the valves 253a, 253b, 253c, and 243a, processing gases such as the oxygen-containing gas, the hydrogen-containing gas, the inert gas, and the like can be supplied into the process chamber 201 through the gas supply pipes 232a, 232b, and 232c.

A gas supply part (gas supply system) mainly includes the first processing gas supply part, the second processing gas supply part, and the inert gas supply part. Although the first processing gas supply part, the second processing gas supply part, and the inert gas supply part are included in the gas supply part because the oxygen gas, the hydrogen gas, and the inert gas are used here, the present disclosure is not limited thereto as long as the gas supply part has a structure capable of supplying a gas.

The substrate processing apparatus according to the present embodiments is configured to perform an oxidation process by supplying an O₂ gas as an oxygen-containing gas from an oxygen-containing gas supply system. However, a nitrogen-containing gas supply system for supplying a nitrogen-containing gas into the process chamber 201 may be provided instead of the oxygen-containing gas supply system. According to the substrate processing apparatus configured as above, a nitridation process can be performed instead of the oxidation process of the substrate. In this case, for example, a N₂ gas supply source as a nitrogen-containing gas supply source is provided instead of the O₂ gas supply source 250a, and the oxygen-containing gas supply pipe 232a is configured as a nitrogen-containing gas supply pipe.

### Exhaust Part

A gas exhaust port 235 for exhausting the reaction gas from the interior of the process chamber 201 is installed at the side wall of the lower container 211. The upstream end of a gas exhaust pipe 231 is connected to the lower container 211 so as to communicate with the gas exhaust port 235. An APC (auto pressure controller) valve 242 as a pressure regulator (pressure adjustment part), a valve 243b as an opening/closing valve, and a vacuum pump 246 as a vacuum exhaust device are installed at the gas exhaust pipe 231 in order from the upstream side.

An exhaust part according to the present embodiments mainly includes the gas exhaust pipe 231, the APC valve 242, and the valve 243b. The exhaust part may include the vacuum pump 246.

### Plasma-Generating Part

A plurality of spiral resonance coils 212 are installed at the outer peripheral portion of the process chamber 201, that is, outside the side wall of the upper container 210, so as to surround the process chamber 201. Each of the resonance coils 212 includes a resonance coil 212a as a first electrode and a resonance coil 212b as a second electrode. A conductor forming the resonance coil 212a and a conductor forming the resonance coil 212b are alternately arranged in the vertical direction. The resonance coil 212a is also referred to as a first resonance coil, and the resonance coil 212b is also referred to as a second resonance coil. The conductor of the resonance coil 212a is also called a first conductor, and the conductor of the resonance coil 212b is also referred to as a second conductor.

A RF sensor 272, a high-frequency power supply 273, and a matching device 274 for matching the impedance and output frequency of the high-frequency power supply 273 are connected to the resonance coil 212a.

The high-frequency power supply 273 supplies high-frequency power (RF power) to the resonance coil 212a. The RF sensor 272 is installed at the output side of the high-frequency power supply 273 and monitors information on a traveling wave and a reflected wave of the supplied high-frequency power. The reflected wave power monitored by the RF sensor 272 is input to the matching device 274, and the matching device 274 controls the impedance and the frequency of the output high-frequency power of the high-frequency power supply 273 based on the information on the reflected wave input from the RF sensor 272 so that the reflected wave is minimized.

The high-frequency power supply 273 includes a power supply control part (control circuit) including a high-frequency oscillation circuit and a preamplifier for defining an oscillation frequency and an output, and an amplifier (output circuit) for amplifying the output to a predetermined output. The power supply control part controls the amplifier based on output conditions related to a frequency and power preset via an operation panel. The amplifier supplies constant high-frequency power to the resonance coil 212a via a transmission line.

The high-frequency power supply 273, the matching device 274, and the RF sensor 272 are collectively referred to as a high-frequency power supply part 271. Any one of the high-frequency power supply 273, the matching device 274, and the RF sensor 272, or a combination thereof, may be referred to as a high-frequency power supply part 271. The high-frequency power supply part 271 is also referred to as a first high-frequency power supply part.

A RF sensor 282, a high-frequency power supply 283, and a matching device 284 for matching the impedance and output frequency of the high-frequency power supply 283 are connected to the resonance coil 212b.

The high-frequency power supply 283 supplies high-frequency power (RF power) to the resonance coil 212b. The RF sensor 282 is installed at the output side of the high-frequency power supply 283 and monitors information on a traveling wave and a reflected wave of the supplied high-frequency power. The reflected wave power monitored by the RF sensor 282 is input to the matching device 284, and the matching device 284 controls the impedance and the frequency of the output high-frequency power of the high-frequency power supply 283 based on the information on the reflected wave input from the RF sensor 282 so that the reflected wave is minimized.

The high-frequency power supply 283 includes a power supply control part (control circuit) including a high-frequency oscillation circuit and a preamplifier for defining an oscillation frequency and an output, and an amplifier (output circuit) for amplifying the output to a predetermined output. The power supply control part controls the amplifier based on output conditions related to a frequency and power preset via the operation panel. The amplifier supplies constant high-frequency power to the resonance coil 212b via a transmission line.

The high-frequency power supply 283, the matching device 284, and the RF sensor 282 are collectively referred to as a high-frequency power supply part 281. Any one of the high-frequency power supply 283, the matching device 284, and the RF sensor 282, or a combination thereof, may be referred to as a high-frequency power supply part 281. The high-frequency power supply part 281 is also referred to as a second high-frequency power supply part. The first high-frequency power supply part and the second high-frequency power supply part 281 are collectively referred to as a high-frequency power supply part.

The winding diameter, winding pitch, and number of turns of each of the resonance coil 212a and the resonance coil 212b are set so as to resonate at a constant wavelength in order to form a standing wave having a predetermined wavelength. That is, the electrical length of the resonance coil 212a is set to a length corresponding to an integral multiple (1 time, 2 times, . . . ) of one wavelength at a predetermined frequency of the high-frequency power supplied from the high-frequency power supply part 271. The electrical length of the resonance coil 212b is set to a length corresponding to an integral multiple (1 time, 2 times, . . . ) of one wavelength at a predetermined frequency of the high-frequency power supplied from the high-frequency power supply part 281.

Specifically, in consideration of the applied power, the intensity of a generated magnetic field, the outer shape of a device to be applied, and the like, each of the resonance coils 212a and 212b may have an effective sectional area of 50 to 300 mm² and a coil diameter of 200 to 500 mm so that a magnetic field of about 0.01 to 10 Gauss can be generated by high-frequency power of 800 kHz to 50 MHz and 0.5 to 5 KW, for example, and may be wound about 2 to 60 times around the outer periphery of a room forming the plasma generation space 201a.

For example, when the frequency is 13.56 MHz, the length of one wavelength is about 22 meters. When the frequency is 27.12 MHz, the length of one wavelength is about 11 meters. As an example, the electrical lengths of the resonance coil 212a and the resonance coil 212b are provided so as to be equal to the length (1 time) of one wavelength. In the present embodiments, the frequency of the high-frequency power is set to 27.12 MHz, and the electrical length of the resonance coil 212 is set to the length (about 11 meters) of one wavelength.

The winding pitch of the resonance coil 212a is set, for example, at equal intervals of 24.5 mm. Further, the winding diameter of the resonance coil 212a is set to be larger than the diameter of the substrate 200. In the present embodiments, the diameter of the substrate 200 is set to 300 mm, and the winding diameter of the resonance coil 212a is set to be 500 mm, which is larger than the diameter of the substrate 200.

The winding pitch of the resonance coil 212b is set, for example, at equal intervals of 24.5 mm. Further, the winding diameter of the resonance coil 212b is set to be larger than the diameter of the substrate 200. In the present embodiments, the diameter of the substrate 200 is set to 300 mm, and the winding diameter of the resonance coil 212b is set to be 500 mm, which is larger than the diameter of the substrate 200.

The resonance coil 212a and the resonance coil 212b are arranged so that the antinodes of the standing wave do not overlap. The distance between the resonance coil 212a and the resonance coil 212b is set to a distance apart that does not cause arc discharge between the conductors of the respective resonance coils.

The material of the resonance coil 212a and the resonance coil 212b may be a copper pipe, a copper thin plate, an aluminum pipe, an aluminum thin plate, a material obtained by depositing copper or aluminum on a polymer belt, or the like. The resonance coil 212 is formed in a flat plate shape from an insulating material, and is supported by a plurality of supports (not shown) vertically installed at the upper end surface of a base plate 248.

Both ends of each of the resonance coil 212a and the resonance coil 212b are electrically grounded, and at least one end selected from the group thereof is grounded via a movable tap 213 (213a and 213b) in order to finely adjust the electrical length of the resonance coil at the time of initial installation of the apparatus or at the time of change of processing conditions. Reference numeral 214 (214a and 214b) in FIG. 1 denotes the other fixed ground.

The position of the movable tap 213a is adjusted so that the resonance characteristics of the resonance coil 212a are substantially equal to those of the high-frequency power supply 273. Further, in order to finely adjust the impedance of the resonance coil 212a at the time of initial installation of the apparatus or at the time of change of processing conditions, a power feeder is formed by the movable tap 215a between the grounded both ends of the resonance coil 212a.

The position of the movable tap 213b is adjusted so that the resonance characteristics of the resonance coil 212b are substantially equal to those of the high-frequency power supply 283. Further, in order to finely adjust the impedance of the resonance coil 212b at the time of initial installation of the apparatus or at the time of change of processing conditions, a power feeder is formed by the movable tap 215b between the grounded both ends of the resonance coil 212b.

Since each of the resonance coil 212a and the resonance coil 212b includes the variable ground and the variable power feeder, the resonance frequency and the load impedance of the process chamber 201 can be adjusted more easily, as will be described below.

Further, a waveform adjustment circuit (not shown) composed of a resonance coil and a shield is inserted in one end (or the other end or both ends) of each of the resonance coils 212a and 212b so that a phase current and an anti-phase current flow symmetrically with respect to the electrical midpoint of each of the resonance coils 212a and 212b. The waveform adjustment circuit is configured as an open circuit by setting each of the resonance coils 212a and 212b to an electrically disconnected state or an electrically equivalent state. The end of each of the resonance coils 212a and 212b may be non-grounded by a choke series resistor and may be DC-connected to a fixed reference potential.

A shielding plate 223 is installed to shield an outer electric field of the resonance coil 212 and to form a capacitance component (C component) necessary for forming a resonance circuit between the shielding plate 223 and the resonance coil 212a or 212b. The shielding plate 223 is generally made of a conductive material such as an aluminum alloy and is formed in a cylindrical shape. The shielding plate 223 is disposed at a distance of about 5 to 150 mm from the outer periphery of each of the resonance coils 212a and 212b. Although the shielding plate 223 is usually grounded so that its potential is equal to the potentials of both ends of the resonance coils 212a and 212b, one end or both ends of the shielding plate 223 are configured so that a tap position can be adjusted in order to accurately set the number of resonances of the resonance coils 212a and 212b. Alternatively, in order to accurately set the number of resonances, a trimming capacitance may be inserted between each of the resonance coils 212a and 212b and the shielding plate 223.

A first plasma generation part mainly includes the resonance coil 212a and the first high-frequency power supply part 271. A second plasma generation part mainly includes the resonance coil 212b and the second high-frequency power supply part 281. The first plasma generation part and the second plasma generation part are collectively referred to as a plasma generation part.

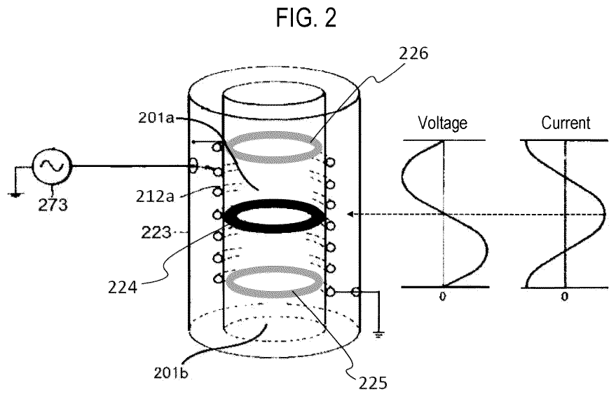

Next, the principle of plasma generation and the properties of generated plasma will be described with reference to FIG. 2. Since the principles of plasma generation of the resonance coils 212a and 212b are the same, only one resonance coil 212a will be described here as an example. In the case of the resonance coil 212b, the RF sensor 272 is replaced with the RF sensor 282, the high-frequency power supply 273 is replaced with the high-frequency power supply 283, and the matching device 274 is replaced with the matching device 284.

The plasma generation circuit formed by the resonance coil 212a is constituted as an RLC parallel resonance circuit. When the wavelength of the high-frequency power supplied from the high-frequency power supply 273 is equal to the electrical length of the resonance coil 212a, the resonance condition of the resonance coil 212a is that the reactance component made by the capacitance component and the inductance component of the resonance coil 212a is canceled out to become pure resistance. However, in the above-described plasma generation circuit, when plasma is generated, the actual resonance frequency fluctuates slightly depending on fluctuation in capacitive coupling between the voltage portion of the resonance coil 212a and the plasma, fluctuation in inductive coupling between the plasma generation space 201a and the plasma, the excited state of the plasma, and the like.

Therefore, in the present embodiments, in order to compensate for the deviation of resonance in the resonance coil 212a when the plasma is generated, the power of the reflected wave from the resonance coil 212a when the plasma is generated is detected by the RF sensor 272, and the matching device 274 has a function of correcting the output of the high-frequency power supply 273 based on the reflected power of the reflected wave.

Specifically, based on the reflected wave power from the resonance coil 212a, when the plasma detected by the RF sensor 272 is generated, the matching device 274 increases or decreases the impedance or output frequency of the high-frequency power supply 273 such that the reflected wave power is minimized. When controlling the impedance, the matching device 274 is constituted by a variable capacitor control circuit that corrects preset impedance. When controlling the frequency, the matching device 274 is constituted by a frequency control circuit that corrects a preset oscillation frequency of the high-frequency power supply 273. The high-frequency power supply 273 and the matching device 274 may be integrated.

With this configuration, in the resonance coil 212a of the present embodiments, as illustrated in FIG. 2, since the high-frequency power by the actual resonance frequency of the resonance coil including the plasma is supplied (or since the high-frequency power is supplied so as to match the actual impedance of the resonance coil including the plasma), a standing wave in which a phase voltage and an anti-phase voltage are always canceled out is formed. When the electrical length of the resonance coil 212a is equal to the wavelength of the high-frequency power, the highest phase current is generated at the electrical midpoint of the resonance coil (a node where the voltage is zero). Therefore, in the vicinity of the electric midpoint, there is almost no capacitive coupling with the process chamber wall and the substrate-mounting table 217, and doughnut-shaped induction plasma 224 having an extremely low electric potential is formed. Further, according to the same principle, plasma 226 and plasma 225 are generated at both ends of the resonance coil.

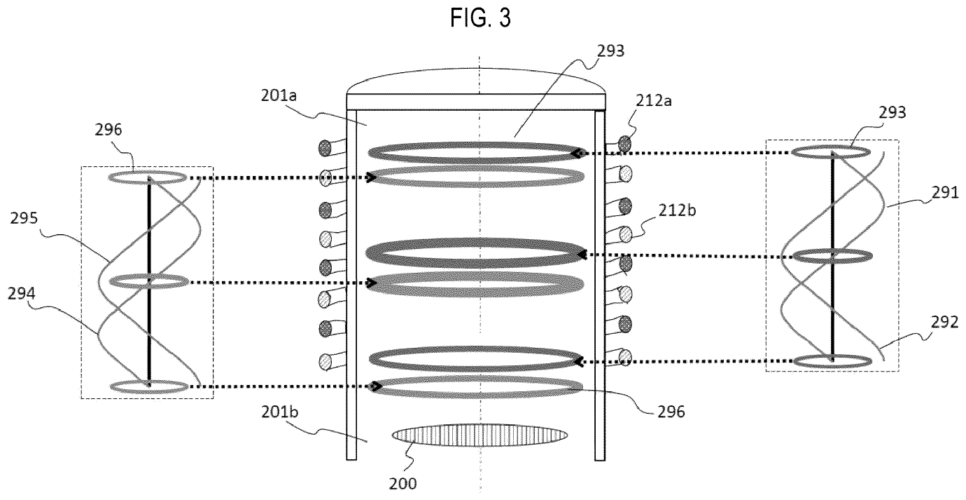

Next, a state in which the resonance coils 212a and 212b are used to generate plasma will be described with reference to FIG. 3.

In FIG. 3, as in FIG. 1, two resonance coils 212a and 212b are installed around the plasma generation space 201a. When high-frequency power is supplied to the resonance coil 212a in a state where a gas is supplied to the plasma generation space 201a, a voltage 291 and a current 292 are generated, and plasma 293 is generated in the plasma generation space 201a, according to the above-described principle.

Similarly, when high-frequency power is supplied to the resonance coil 212b in a state where a gas is supplied to the plasma generation space 201a, a voltage 294 and a current 295 are generated, and plasma 296 is generated in the plasma generation space 201a, according to the above-described principle.

In this way, by using a plurality of resonance coils, a larger amount of plasma can be generated than a case where a single resonance coil is used. That is, a larger amount of radical components in the plasma can be generated. Therefore, the amount of radicals that can reach the bottom of a deep groove can be increased to facilitate treatment on the bottom of the deep groove.

Next, timings of generation of the plasma 293 and the plasma 296 will be described. First, as a comparative example, a case where the plasma 293 and the plasma 296 are simultaneously present in the plasma generation space 201a is considered.

In this case, the high-frequency power is supplied to each resonance coil, but there is a possibility that adjacent resonance coils may have an electrical effect. Then, the phase of each resonance coil is shifted. As a result, a standing wave cannot be generated in each resonance coil.

On the other hand, it is conceivable to separate adjacent resonance coils by a distance that does not affect the electrical effect. However, in this case, it is necessary to increase the distance between the resonance coils. As a result, the height of the upper container 210 must be increased. The increased height of the upper container 210 increases a distance between the plasma generated above the container (e.g., the plasma 226 in FIG. 2) and the substrate 200, which increases a distance by which the plasma travels, and thus increases the amount of plasma deactivation. Therefore, it is desirable to keep the height of the upper container 210 as low as possible.

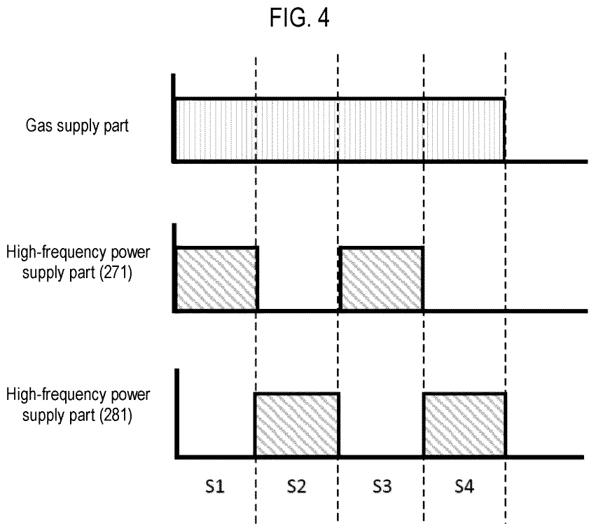

Therefore, it is considered to intermittently supply high-frequency power to each resonance coil. This will be described with reference to FIG. 4. FIG. 4 is a view for explaining the operations of the gas supply part, the high-frequency power supply part 271, and the high-frequency power supply part 281 in a processing step S240 to be described below. In FIG. 4, the vertical axis represents ON/OFF, and the horizontal axis represents time.

The gas supply part supplies a gas continuously. Meanwhile, the high-frequency power supply part 271 and the high-frequency power supply part 281 intermittently supply high-frequency power. The supply period of the high-frequency power from the high-frequency power supply part 271 does not overlap with the supply period of the high-frequency power from the high-frequency power supply part 281.

Specifically, in Step 1 (step S1), a gas is supplied from the gas supply part, high-frequency power is supplied from the high-frequency power supply part 271 to the resonance coil 212a for a predetermined time, and no high-frequency power is supplied from the high-frequency power supply part 281 to the resonance coil 212b. By doing so, the plasma 296 is not generated and the plasma 293 is generated in the plasma generation space 201a. Similarly, in Step 3 (step S3), high-frequency power is supplied from the high-frequency power supply part 271 to the resonance coil 212a, and the supply of the high-frequency power from the high-frequency power supply part 281 to the resonance coil 212b is stopped.

In Step 2 (step S2), a gas is supplied from the gas supply part, high-frequency power is supplied from the high-frequency power supply part 281 to the resonance coil 212b, and the supply of the high-frequency power from the high-frequency power supply part 271 to the resonance coil 212a is stopped. By doing so, the plasma 293 is not generated and the plasma 296 is generated in the plasma generation space 201a. the same applies to Step 4 (step S4).

This control prevents the plasma 293 and the plasma 296 from being simultaneously present in the plasma generation space 201a. Accordingly, the resonance coils can generate a standing wave without being electrically influenced by each other.

Next, the time of switching between the supply of the high-frequency power from the high-frequency power supply part 271 and the supply of the high-frequency power from the high-frequency power supply part 281 will be described. To ensure that there is no electrical influence, a switching time may be provided between the supply of the high-frequency power to the resonance coil 212a and the supply of the high-frequency power to the resonance coil 212b, in which no high-frequency power is supplied to any of the coils.

For the switching time, for example, when shifting from step S1 to step S2, the high-frequency power is supplied to the resonance coil 212b before a speed of an electron in the plasma 293 generated in the resonance coil 212a decreases. When shifting from step S2 to step S3, the high-frequency power is supplied to the resonance coil 212a before the speed of the electron in the plasma 296 generated in the resonance coil 212b decreases. This is because maintaining the speed of the electron can maintain the active state of many generated radicals.

### Control Part

A controller 221 as a control part is configured to control the APC valve 242, the valve 243b, and the vacuum pump 246 via a signal line A, the substrate-mounting-table-elevating mechanism 268 via a signal line B, a heater power adjustment mechanism 276 and the impedance-variable mechanism 275 via a signal line C, the gate valve 244 via a signal line D, the high-frequency power supplies 273 and 283 and the matching devices 274 and 284 via a signal line E, and the MFCs 252a to 252c and the valves 253a to 253c and 243a via a signal line F.

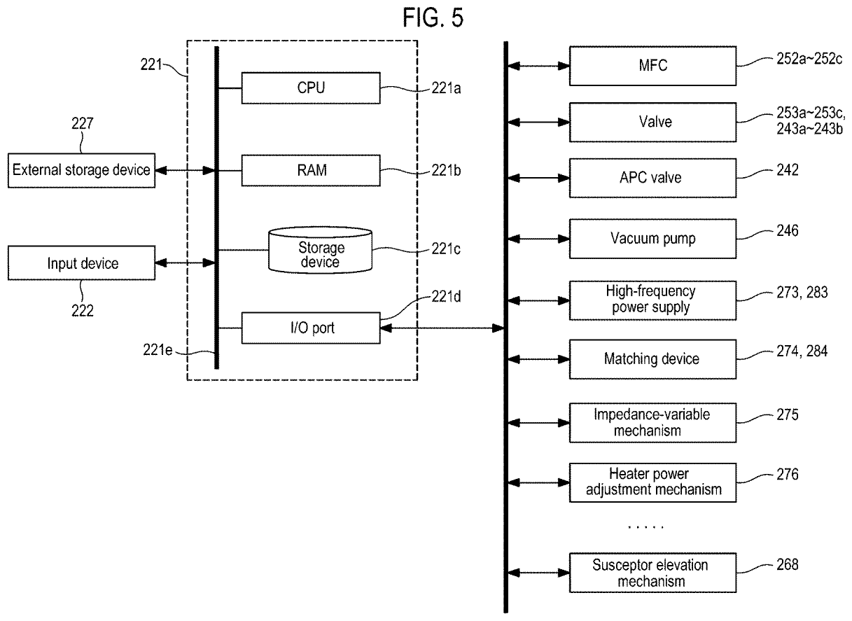

As illustrated in FIG. 5, the controller 221, which is the control part, is configured as a computer including a CPU (central processing unit) 221a, a RAM (random access memory) 221b, a storage device 221c, and an I/O port 221d. The RAM 221b, the storage device 221c, and the I/O port 221d are configured to exchange data with the CPU 221a via an internal bus 221e. An input/output device 222 configured as, for example, a touch panel, a display, or the like is connected to the controller 221.

The storage device 221c is configured by, for example, a flash memory, a HDD (hard disk drive), or the like. A control program for controlling the operation of the substrate processing apparatus, process recipes in which procedures and conditions of substrate processing to be described below, and the like are readably stored in the storage device 221c. The process recipes are combined to obtain a predetermined result by causing the controller 221 to execute the respective procedures in the substrate-processing process to be described below, and function as a program. Hereinafter, the process recipes and the control program are collectively referred to simply as a program. In the present disclosure, the term “program” may include only a process recipe, only a control program, or both. Further, the RAM 221b is configured as a memory area (work area) in which programs, data, and the like read by the CPU 221a are temporarily held.

The I/O port 221d is connected to the MFCs 252a to 252c, the valves 253a to 253c, 243a and 243b, the gate valve 244, the APC valve 242, the vacuum pump 246, the RF sensor 272, the high-frequency power supply 273, the matching device 274, the substrate-mounting-table-elevating mechanism 268, the impedance-variable mechanism 275, the heater power adjustment mechanism 276, and the like.

The CPU 221a is configured to read and execute the control program from the storage device 221c and to read the process recipes from the storage device 221c in response to an input of an operation command from the input/output device 222. Then, the CPU 221a can control the opening-degree-adjusting operation of the APC valve 242, the opening/closing operation of the valve 243b, and the start/stop of the vacuum pump 246 via the I/O port 221d and the signal line A, the elevating operation of the substrate-mounting-table-elevating mechanism 268 via the signal line B, the adjusting operation of the amount of power supplied to the heater 217b (temperature-adjusting operation) by the heater power adjustment mechanism 276 and the impedance-value-adjusting operation by the impedance-variable mechanism 275 via the signal line C, the opening/closing operation of the gate valve 244 via the signal line D, the operations of the RF sensors 272 and 282, the matching devices 274 and 284, and the high-frequency power supplies 273 and 283 via the signal line E, the flow-rate-adjusting operation of various gases by the MFCs 252a to 252c and the opening/closing operation of the valves 253a to 253c and 243a via the signal line F, and so on according to the contents of the read process recipes.

The controller 221 can be configured by installing, in a computer, the above-mentioned program stored in an external storage device (for example, a magnetic tape, a magnetic disk such as a flexible disk or a hard disk, an optical disk such as a CD or a DVD, a magneto-optical disk such as a MO, or a semiconductor memory such as a USB memory or a memory card) 227. The storage device 221c and the external storage device 227 are configured as a non-transitory computer-readable recording medium. Hereinafter, these are collectively referred to simply as a recording medium. In the present disclosure, when the term “recording medium” is used, it may include the storage device 221c only, the external storage device 227 only, or both. A communication means such as the Internet or a dedicated line may be used to supply the program to the computer without using the external storage device 227.

### (2) Substrate-Processing Process

Next, a substrate-processing process according to the present embodiments will be described mainly with reference to FIG. 7. FIG. 7 is a flowchart illustrating a substrate-processing process according to the present embodiments. The substrate-processing process according to the present embodiments is performed by the above-described processing apparatus 100, as one of processes of manufacturing a semiconductor device such as a flash memory or the like. In the following description, the operations of various parts of the processing apparatus 100 are controlled by the controller 221.

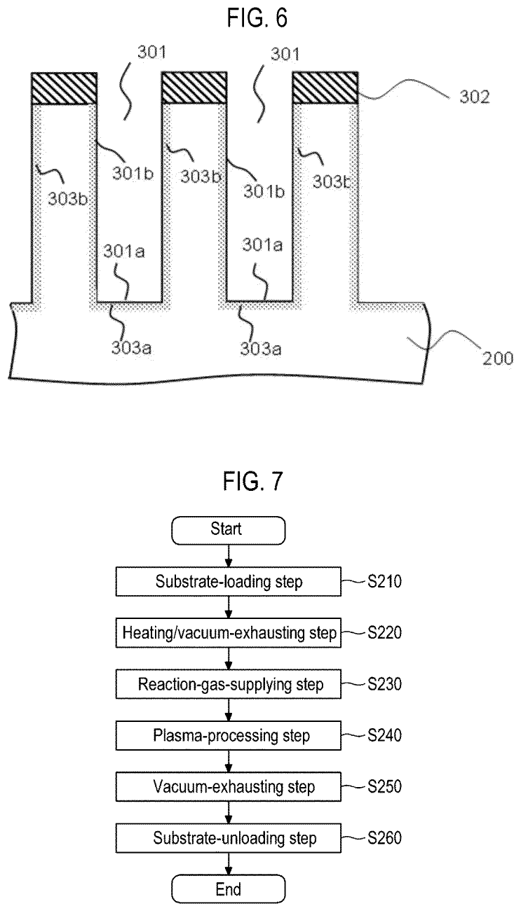

For example, as illustrated in FIG. 6, a trench 301 having at least a surface formed of a silicon layer and having an unevenness having a high aspect ratio is formed in advance on the surface of a substrate 200 to be processed in the substrate-processing process according to the present embodiments. In the present embodiments, an oxidation process using plasma is performed on the silicon layer exposed on the inner wall of the trench 301. The trench 301 is formed, for example, by forming a mask layer 302 having a predetermined pattern on the substrate 200 and etching the surface of the substrate 200 to a predetermined depth.

### Substrate-Loading Step S210

A substrate-loading step S210 will be described. First, the substrate 200 is loaded into the process chamber 201. Specifically, the substrate-mounting-table-elevating mechanism 268 lowers the substrate-mounting table 217 to a transfer position of the substrate 200, and causes the wafer push-up pins 266 to pass through the through-holes 217a of the substrate-mounting table 217. As a result, the wafer push-up pins 266 protrude from the surface of the substrate-mounting table 217 by a predetermined height.

Subsequently, the gate valve 244 is opened, and the substrate 200 is loaded into the process chamber 201 from a vacuum transfer chamber adjacent to the process chamber 201 by using a wafer transfer mechanism (not shown). The loaded substrate 200 is supported in a horizontal posture on the wafer push-up pins 266 protruding from the surface of the substrate-mounting table 217. When the substrate 200 is loaded into the process chamber 201, the wafer transfer mechanism is retracted outside the process chamber 201, and the gate valve 244 is closed to seal the interior of the process chamber 201. Then, the substrate-mounting-table-elevating mechanism 268 raises the substrate-mounting table 217 so that the substrate 200 is supported on the upper surface of the substrate-mounting table 217.

### Heating/Vacuum-Exhausting Step S220

A heating/vacuum-exhausting step S220 will be described. In this step, the substrate 200 loaded into the process chamber 201 is heated. The heater 217b is heated in advance. When the substrate 200 is held on the substrate-mounting table 217 in which the heater 217b is embedded, the substrate 200 is heated to a predetermined value within a range from, for example, 150 to 750 degrees C. In this step, the substrate 200 is heated to 600 degrees C. Further, while the substrate 200 is being heated, the interior side of the process chamber 201 is vacuum-exhausted by the vacuum pump 246 through the gas exhaust pipe 231 to set the internal pressure of the process chamber 201 to a predetermined value. The vacuum pump 246 is operated at least until a substrate-unloading step S260 to be described below is ended.

### Reaction-Gas-Supplying Step S230

A reaction-gas-supplying step S230 will be described. Supply of an O₂ gas, which is an oxygen-containing gas, and a H₂ gas, which is a hydrogen-containing gas, as a reaction gas is started. Specifically, while the valves 253a and 253b are opened and the flow rates of the gases are controlled by the MFCs 252a and 252b, the supply of the O₂ gas and the H₂ gas into the process chamber 201 is started. At this time, the flow rate of the O₂ gas is set to a predetermined value within a range of, for example, 20 to 2,000 sccm, specifically 20 to 1,000 sccm. Further, the flow rate of the H₂ gas is set to a predetermined value within a range of, for example, 20 to 1,000 sccm, specifically 20 to 500 sccm. As a more suitable example, it is preferable that the total flow rate of the O₂ gas and the H₂ gas is set to 1,000 sccm and the flow rate ratio is set to O₂/H₂≥950/50.

Further, the exhaust of the interior of the process chamber 201 is controlled by adjusting the opening degree of the APC valve 242 so that the interior of the process chamber 201 has a predetermined pressure within a range of, for example, 1 to 250 Pa, specifically 50 to 200 Pa, more specifically about 150 Pa. In this way, while the interior of the process chamber 201 is appropriately exhausted, the supply of the O₂ gas and the H₂ gas is continued until a plasma-processing step S240 to be described below is ended.

### Plasma-Processing Step S240

A plasma-processing step S240 will be described with reference to FIG. 4. In step S1, a gas is supplied from the gas supply part, high-frequency power is supplied from the high-frequency power supply part 271 to the resonance coil 212a, and no high-frequency power is supplied from the high-frequency power supply part 281 to the resonance coil 212b.

Specifically, when the internal pressure of the process chamber 201 is stabilized, application of the high-frequency power from the high-frequency power supply 273 to the resonance coil 212a via the RF sensor 272 is started. In the present embodiments, high-frequency power of 27.12 MHz is supplied from the high-frequency power supply 273 to the resonance coil 212. The high-frequency power supplied to the resonance coil 212 is predetermined power within a range of, for example, 100 to 5,000 W, specifically 100 to 3,500 W, more specifically about 3,500 W. If the power is lower than 100 W, it is difficult to stably generate plasma discharge.

Thereby, a high-frequency electric field is formed in the plasma generation space 201a into which the O₂ gas and the H₂ gas are supplied, and the doughnut-shaped induction plasma 293 having a high plasma density is excited by this electric field. The O₂ gas and the H₂ gas in the form of plasma are dissociated to generate reactive species such as oxygen ions or oxygen radicals containing oxygen (oxygen active species), hydrogen ions or hydrogen radicals containing hydrogen (hydrogen active species), and the like.

As described above, when the electrical length of the resonance coil 212a is equal to the wavelength of the high-frequency power, since there is almost no capacitive coupling with the process chamber wall and the substrate-mounting table in the plasma generation space 201a, the doughnut-shaped induction plasma 293 having an extremely low electrical potential is excited. Since plasma having an extremely low electric potential is generated, generation of a sheath on the wall of the plasma generation space 201a or on the substrate-mounting table 217 can be prevented. Therefore, in present embodiments, ions in the plasma are not accelerated.

The radicals generated by the induction plasma and the ions in a non-accelerated state are uniformly supplied into the trench 301 at the substrate 200 held on the substrate-mounting table 217 in the substrate-processing space 201b. The supplied radicals and ions uniformly react with the bottom wall 301a and the side wall 301b to modify the silicon layer on the surface into a silicon oxide layer 303 having good step coverage. Specifically, the bottom wall 301a is modified into an oxide layer 303a, and the side wall 301b is modified into an oxide layer 303b.

In addition, since acceleration of ions is prevented, the substrate 200 can be prevented from being damaged by the accelerated ions, and a sputtering effect on the peripheral wall of the plasma generation space can be suppressed to prevent damage to the peripheral wall of the plasma generation space 201a.

In addition, since the matching device 274 attached to the high-frequency power supply 273 compensates for the reflected wave power due to impedance mismatch generated in the resonance coil 212a at the high-frequency power supply 273 side to complement the decrease in the effective load power, the initial level of high-frequency power can always be reliably supplied to the resonance coil 212a to stabilize the plasma. Therefore, the substrate 200 held in the substrate-processing space 201b can be uniformly processed at a constant rate. Thereafter, when a predetermined processing time, for example, 10 to 300 seconds, elapses, the process proceeds to step S2.

Subsequently, step S2 will be described. In step S2, a gas is supplied from the gas supply part, high-frequency power is supplied from the high-frequency power supply part 281 to the resonance coil 212b, and the supply of the high-frequency power from the high-frequency power supply part 271 to the resonance coil 212a is stopped.

Specifically, as in step S1, when the internal pressure of the process chamber 201 is stabilized, application of the high-frequency power from the high-frequency power supply 283 to the resonance coil 212b via the RF sensor 282 is started. In the present embodiments, high-frequency power of 27.12 MHz is supplied from the high-frequency power supply 283 to the resonance coil 212b. The high-frequency power supplied to the resonance coil 212 is predetermined power within a range of, for example, 100 to 5,000 W, specifically 100 to 3,500 W, more specifically about 3,500 W. If the power is lower than 100 W, it is difficult to stably generate plasma discharge.

Thereby, a high-frequency electric field is formed in the plasma generation space 201a into which the O₂ gas and the H₂ gas are supplied, and the doughnut-shaped induction plasma 296 having a high plasma density is excited by this electric field. In addition, energy is added to the radicals generated in step S1 by this electric field to extend the life of the radicals. The O₂ gas and the H₂ gas in the form of plasma are dissociated to generate reactive species such as oxygen ions or oxygen radicals containing oxygen (oxygen active species), hydrogen ions or hydrogen radicals containing hydrogen (hydrogen active species), and the like.

As described above, when the electrical length of the resonance coil 212b is equal to the wavelength of the high-frequency power, since there is almost no capacitive coupling with the process chamber wall and the substrate-mounting table in the plasma generation space 201a, the doughnut-shaped induction plasma 296 having an extremely low electrical potential is excited.

The radicals generated by the induction plasma, the radicals generated in step S1 and having the life extended in step S2, and the ions in a non-accelerated state are uniformly supplied into the trench 301 at the substrate 200 held on the substrate-mounting table 217 in the substrate-processing space 201b. The supplied radicals are not deactivated and are uniformly supplied and react with the bottom wall 301a and the side wall 301b to modify the silicon layer on the surface into a silicon oxide layer having good step coverage.

Even in step S2, since acceleration of ions is prevented, the substrate 200 can be prevented from being damaged by the accelerated ions, and a sputtering effect on the peripheral wall of the plasma generation space can be suppressed to prevent damage to the peripheral wall of the plasma generation space 201a.

In addition, since the matching device 284 attached to the high-frequency power supply 283 compensates for the reflected wave power due to impedance mismatch generated in the resonance coil 212b at the high-frequency power supply 283 side to complement the decrease in the effective load power, the initial level of high-frequency power can always be reliably supplied to the resonance coil 212b to stabilize the plasma. Therefore, the substrate 200 held in the substrate-processing space 201b can be uniformly processed at a constant rate.

Thereafter, when a predetermined processing time, for example, 10 to 300 seconds, elapses, the supply of the high-frequency power from the high-frequency power supply part 281 to the resonance coil 212b is stopped.

In addition, the valves 253a and 253b are closed to stop the supply of the O₂ gas and the H₂ gas into the process chamber 201. Thus, the plasma-processing step S240 is ended.

In addition, depending on the width and depth of the groove, the height of the upper container 210a, and the like, step 3 and step 4 may be further performed, or steps S1 to S4 may be repeatedly performed.

### Vacuum-Exhausting Step S250

When the supply of the O₂ gas and the H₂ gas is stopped, the interior of the process chamber 201 is vacuum-exhausted via the gas exhaust pipe 231. Thus, the O₂ gas and the H₂ gas in the process chamber 201 and other exhaust gas generated by reaction of these gases are exhausted to the outside of the process chamber 201. After that, the opening degree of the APC valve 242 is adjusted to adjust the internal pressure of the process chamber 201 to the same pressure (for example, 100 Pa) as the vacuum transfer chamber (the unloading destination of the substrate 200) (not shown) adjacent to the process chamber 201.

### Substrate-Unloading Step S260

When the internal pressure of the process chamber 201 reaches a predetermined pressure, the substrate-mounting table 217 is lowered to the transfer position of the substrate 200, and the substrate 200 is supported on the wafer push-up pins 266. Then, the gate valve 244 is opened, and the substrate 200 is unloaded from the process chamber 201 by using the wafer transfer mechanism. Thus, the substrate-processing process according to the present embodiments is completed.

An example in which the O₂ gas and the H₂ gas are plasma-excited to perform the plasma processing on the substrate has been illustrated in the present embodiments. However, the present disclosure is not limited thereto. For example, instead of the O₂ gas, a N₂ gas may be supplied into the process chamber 201, and the N₂ gas and the H₂ gas may be plasma-excited to perform a nitridation process to the substrate. In this case, the processing apparatus 100 including the above-described nitrogen-containing gas supply system instead of the above-described oxygen-containing gas supply system can be used.

Further, although two high-frequency power supply parts 271 and 281 are used here, it is sufficient if the supply of high-frequency power to the resonance coils does not overlap. For example, one high-frequency power supply part may be connected to the resonance coils 212a and 212b via a switch. In this case, in step S1, the resonance coil 212a is connected to the high-frequency power supply part, and in step S2, a switch is switched to connect the resonance coil 212b to the high-frequency power supply part.

Further, although the description has been made using two resonance coils, the present disclosure is not limited thereto. For example, three or more resonance coils may be used.

### Other Embodiments

An example in which the oxidation process or the nitridation process to the substrate surface by using plasma is performed has been illustrated in the above-described embodiments. However, the present disclosure is not limited to these processes but is applicable to any technology that performs a process to a substrate by using plasma. For example, the present disclosure can be applied to a modification process or doping process to a film formed on a substrate surface using plasma, a reduction process of an oxide film, an etching process to the film, an ashing process of a resist, and the like.

According to the present disclosure in some embodiments, it is possible to provide a technique capable of uniformly treating the interior of a groove having a high aspect ratio.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate comprising:
loading a substrate including an unevenness into a process chamber including a substrate-mounting table;
a first step of, in a state in which a gas is supplied from a gas supply into the process chamber, forming plasma in the process chamber by supplying high-frequency power by a high-frequency power supplier to a first resonance coil, which is configured by a first conductor that is wound to surround the process chamber, during a first predetermined time period; and
a second step of, in a state in which the gas is supplied from the gas supply into the process chamber, processing the substrate by supplying high-frequency power by the high-frequency power supplier to a second resonance coil, which is configured by a second conductor that is wound to surround the processing chamber, and applying energy to the plasma in the processing chamber, during a second predetermined time period that does not overlap with the first predetermined time period, while an active state of radicals generated in the first predetermined time period is maintained, to thereby supply the radicals to a bottom of the unevenness and enable a layer constituting the unevenness to be modified,
wherein the second resonance coil is configured to be alternately arranged with the first conductor in a vertical direction on a side of the processing chamber.

2. The method of claim 1, wherein the first step and the second step are performed in a state in which the first conductor and the second conductor are set at a distance apart that does not cause arc discharge between the first conductor and the second conductor.

3. The method of claim 1, wherein the first step and the second step are performed in a state in which the first conductor and the second conductor are each disposed at positions where an antinode of a standing wave of the first resonance coil does not overlap with an antinode of a standing wave of the second resonance coil.

4. The method of claim 1, wherein power supply to one of the first resonance coil and the second resonance coil is switched to power supply to the other of the first resonance coil and the second resonance coil before a speed of an electron in plasma generated in the one of the first resonance coil and the second resonance coil decreases.

5. The method of claim 1, wherein an electrical length of the first resonance coil is an integral multiple of one wavelength at a predetermined frequency.

6. The method of claim 1, wherein an electrical length of the second resonance coil is an integral multiple of one wavelength at a predetermined frequency.

7. The method of claim 1, wherein the first step and the second step are performed in a state in which an electrical length of the first resonance coil and an electrical length of the second resonance coil are configured to be the same as each other.

8. The method of claim 1, wherein the first step and the second step are performed in a state in which a winding pitch of the first resonance coil and a winding pitch of the second resonance coil are configured to be the same as each other.

9. The method of claim 1, wherein the first step and the second step are performed in a state in which a diameter of each of the first resonance coil and the second resonance coil is greater than a diameter of the substrate.

10. The method of claim 1, wherein the first step and the second step are performed in a state where a diameter of the first resonance coil and a diameter of the second resonance coil are configured to be the same as each other.

11. The method of claim 1, wherein the unevenness is a groove.

12. The method of claim 1, wherein in the first step, the first resonance coil generates a first doughnut-shaped plasma, and
wherein in the second step, the second resonance coil generates a second doughnut-shaped plasma at a height different from a height where the first doughnut-shaped plasma is generated.

13. The method of claim 1, wherein, in the first step, supply of high-frequency power to the second resonance coil is stopped, and
wherein in the second step, supply of high-frequency power to the first resonance coil is stopped.

14. The method of claim 1, wherein a switching time during which high-frequency power is not supplied to the first resonance coil and the second resonance coil is provided between the first step and the second step.

15. The method of claim 14, wherein the switching time is a time until a velocity of electrons in the plasma generated in the first step or the second step decreases.

16. The method of claim 1, wherein in the first step, plasma including radicals and ions is generated, and
wherein in the second step, acceleration of the ions is prevented, and the radicals are activated.

17. The method of claim 1, wherein a combination of the first step and the second step is repeated.

18. A method of manufacturing a semiconductor device, comprising the method according to claim 1.

19. A non-transitory computer-readable recording medium recording a program causing a substrate processing apparatus to execute the method of claim 1.

20. A substrate processing apparatus capable of executing the method of claim 1.
